(19) United States
(12) Patent Application Publication
(10) Pub. No.: US 2003/0037947 A1
(43) Pub. Date: Feb. 27, 2003

(54) Chip scale package with a small surface mounting area

(75) Inventor: Jansen Chiu, Kaohsiung (TW)

Correspondence Address: DOUGHERTY & TROXELL, SUITE 1404, 5205 LEESBURG PIKE, FALLS CHURCH, VA, 22041, US

(73) Assignee: Walton Advance Electronics LTD

(21) Appl. No.: 09/933,730

(22) Filed: Aug. 22, 2001

(51) Int. Cl. H05K 5/06; H01L 23/02

(52) U.S. Cl. 174/52.2; 174/52.4

(57) ABSTRACT

A chip scale package (CSP) is disclosed. The CSP includes a die with bonding pads at the two lateral sides of active surface. A plurality of leads are adhered on the die, each lead has a first end, a second end. A plurality of metal bonding wires electrically connect the first ends of the leads with the die, and a first sealing layer covers the active surface of the die and the metal bonding wires. Each lead also has a protruding portion over the first sealing layer and located between the first end and the second end for outer electrical connection. Thus, the CSP has a smaller surface mounting area.

### FIELD OF THE INVENTION

The present invention is relating to a chip scale package without outer lead, particularly to a chip scale package with bonding pads at the two lateral sides of die.

### BACKGROUND OF THE INVENTION

Conventionally a chip scale package (CSP) includes a semiconductor die sealed by a package body of insulating thermosetting resin for protecting from the injury of hostile environment. A lead frame (leads) is as an electrically connecting carrier of the die for mounting on a printed circuit board. As shown in FIG. 1, a semiconductor package 10 is a Thin Small Outline Package (TSOP) type package having outer leads extending out of two sides of the package body. The semiconductor package 10 with a semiconductor die 11 sealed comprises the die 11, a package body 12 that seals the die 11, and a lead frame for electrical connection. The lead frame has a die pad 16 and a plurality of leads 14. The die 11 is attached to the die pad 16 by adhesive 13 such as silver paste liquid compound, also a plurality of metal bonding wires 15 are used to electrically interconnect the bonding pads of the die 11 with the inner ends of leads 14 inside the package body 12. The outer ends of leads 14 extend outward to outside the package body 12 and bend properly. The surface mounting ends of the semiconductor package 10 to a printed circuit board are the outer end surfaces 14a of leads 14 in which are around outside the two sides of package body 12, and whose width H1 are quiet wide. A large surface mounting area is bad for surface mounting of high density, i.e. only a few of semiconductor package 10 can be surfaced mounted to a printed circuit board with a fixed area.

With small-sized trend of semiconductor package, a semiconductor package with metal pads replacing of outer leads had been brought up from U.S. Pat. No. 6,143,981 “Plastic Integrated Circuit Package And Method And Lead frame For Making The Package” to decrease the surface footprint. As shown in FIG. 2, a semiconductor package 20 comprises a semiconductor die 21, a package body 22, a plurality of metal leads 24, and a metal die pad 26. The die 21 is attached on the die pad 26, and the metal bonding wires 25 electrically connect the bonding pads of the die 21 with the upper surfaces 24a of the leads 24. The lower surfaces 24b of the leads 24 are exposed outside the package body 22 to become the connecting terminals of the semiconductor package 20 for surface mounting to a printed circuit board. However, in the semiconductor package 20 mentioned above, the surface mounting width H2 between two sides of the lower surfaces 24b of leads 24 is still wide because the die pad 26 occupies a large area. Due to the mismatching thermal expansion coefficients of the die 21 and printed circuit board, if the interval between the soldering points of the semiconductor package 20 at two sides or diagonal (i.e. the interval between the lower surface 24b of leads 24 at two sides) is too wide, a bigger thermal stress will be taken so that the soldering points in the lower surfaces 24b of lead 24 at the periphery of the package body 22 may be broken resulting in failure of electrical and mechanical connection.

### SUMMARY

The main object of the present invention is to provide a chip scale package with a small surface mounting area. The lead on the active surface of the die has a protruding portion for becoming an electrically outer connecting terminal, and is carried on the die to replace the die pad. A chip scale package with bonding pads at the two lateral sides of die can achieve a small surface mounting area for high-density bonding to a printed circuit board.

The chip scale package with a small surface mounting area in accordance with the present invention comprises:

a die having an active surface, a plurality of bonding pads formed at the two lateral

sides of the active surface of the die;

a plurality of leads located on the active surface of die, each having a first surface and a second surface to adhere the die, a first end, a second end, and a protruding portion on the first surface and between the first end and the second end, the first end facing the corresponding bonding pad of die, the second end extending to a perimeter of die without bonding pad;

a plurality of metal bonding wires, each metal bonding wire electrically connecting the bonding pad of the die with the first surface at the first end of the corresponding lead; and

a first sealing layer covering the active surface of the die and the metal bonding wires, and at least exposing a surface of the protruding portion of the leads.

### DESCRIPTION OF THE DRAWINGS

FIG. 1 is a cross-sectional view of a conventional TSOP semiconductor package.

FIG. 2 is a cross-sectional view of the semiconductor package disclosed in U.S. Pat. No. 6,143,981“plastic integrated circuit package and method and lead frame for making the package”.

FIG. 3 is a cross-sectional view of the chip scale package in accordance with the first embodiment of the present invention.

FIG. 4 is a bottom perspective view of the chip scale package in accordance with the first embodiment of the present invention.

FIG. 5a is a cross-sectional view of a wafer provided by the method of manufacturing the chip scale package in accordance with the first embodiment of the present invention.

FIG. 5b is a cross-sectional view of a lead frame adhered by the method of manufacturing the chip scale package in accordance with the first embodiment of the present invention.

FIG. 5c is a cross-sectional view of metal bonding wire wire-bonded by the method of manufacturing the chip scale package in accordance with the first embodiment of the present invention.

FIG. 5d is a cross-sectional view of the first sealing layer formed by the method of manufacturing the chip scale package in accordance with the first embodiment of the present invention.

FIG. 5c is a cross-sectional view of the second sealing layer formed by the method of manufacturing the chip scale package in accordance with the first embodiment of the present invention.

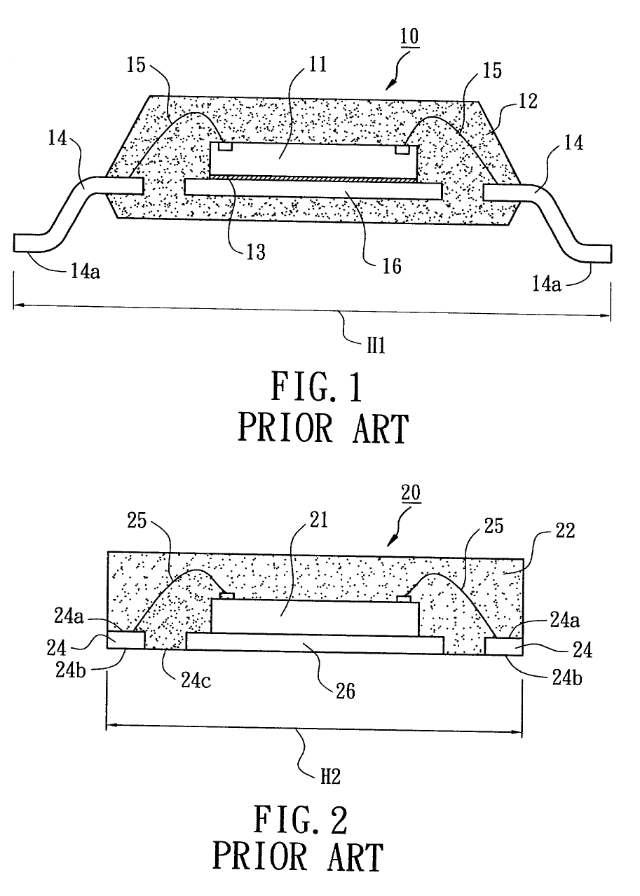

### DETAILED DESCRIPTION OF THE PRESENT INVENTION

Referring to the drawings attached, the present invention will be described by means of the embodiments below.

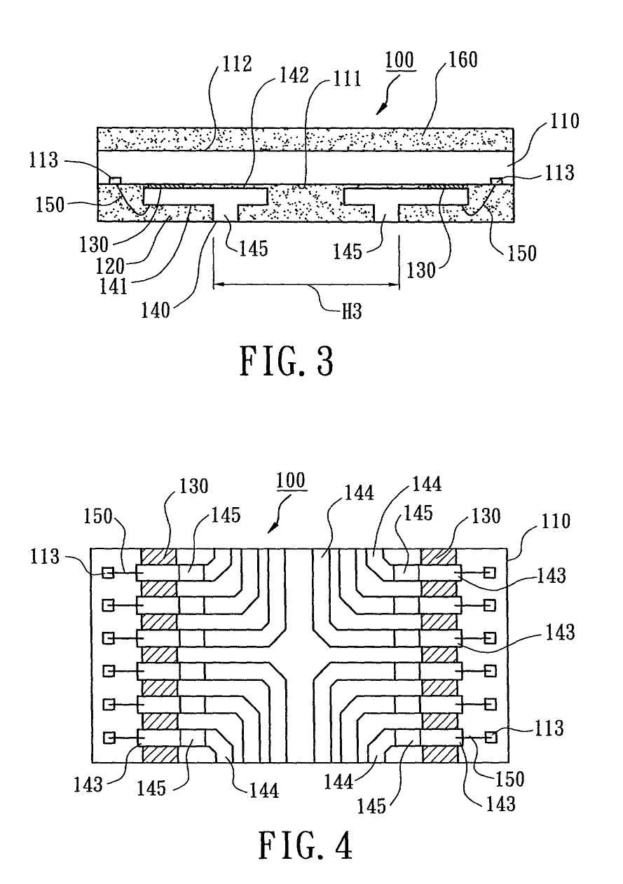

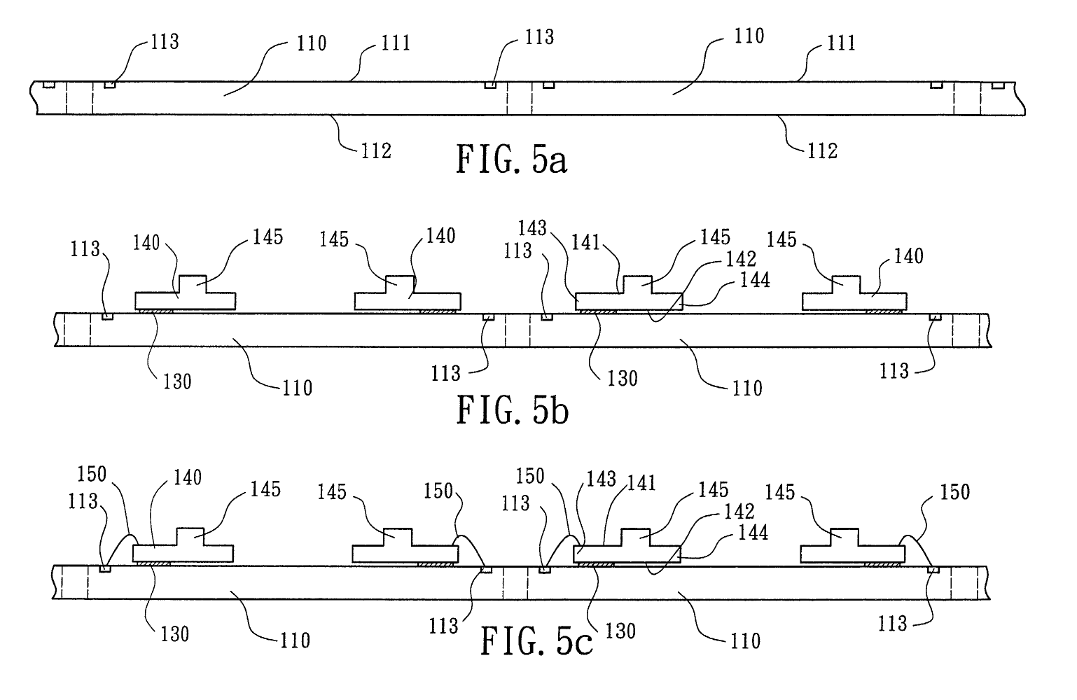

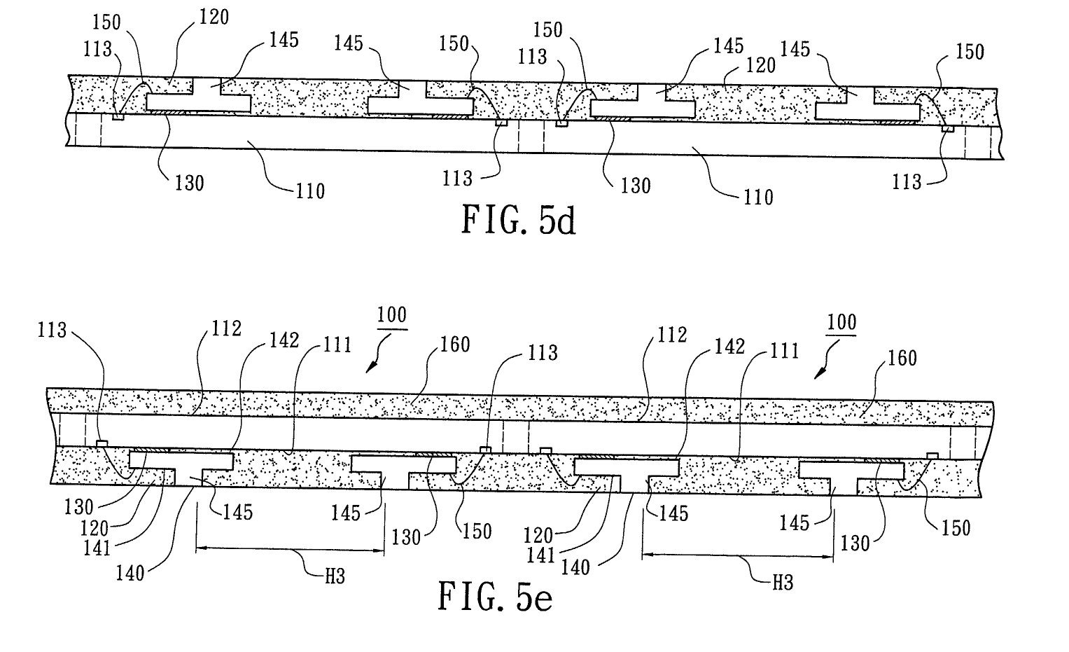

In the first embodiment of the present invention, FIG. 3 is a cross-sectional view of a chip scale package 100, FIG. 4 is a bottom perspective view of the chip scale package 100, from FIG. 5a to FIG. 5e are cross-sectional views of manufacturing process of the chip scale package 100 by wafer level packaging. Chip Scale Package means that the external size of a package 100 is not larger than 1.3 times the size of semiconductor die 110. The chip scale package 100 comprises a die 110, a first sealing layer 120, a plurality of metal bonding wires 150, and a plurality of leads 140.

The die 110 is made of silicon, gallium arsenide or other semiconductor materials. It can be one kind of memory chips such as DRAM, SRAM, flash, DDR or Rambus, etc or microprocessor, logic chip, or radio frequency chip etc. The die 110 has an active surface 111 and a back surface 112. It is familiar that a plurality of bonding pads 113 and integrated circuit elements (not shown in the drawing) are formed on the active surface 111 of the die 110. In this embodiment, the active surface 111 of the die 110 is rectangular shape, and has two wide and two narrow lateral sides. The bonding pads 113 are formed at the two narrow lateral sides of the active surface 111 (as shown in FIG. 3 and 4). The leads 140 are adhered on the active surface 111 of die 110 by the double-sided tape 130.

A plurality of leads 140 are derived from a lead frame, as shown in FIG. 3, each lead 140 has a first surface 141 and a corresponding second surface 142. The second surface 142 is adhered on the active surface 111 of die 110 by double-sided tape 130. It is better that the second surface 142 is a substantially horizontal plane. Besides, as shown in FIG. 4, the lead 140 further comprises a first end 143 and a second end 144. The first end 143 is an end in which the lead 140 extends to a side of die 110 having a bonding pad 113 for connecting the metal bonding wire 150, the metal bonding wires 150 electrically connect the bonding pads 113 of the die 110 with the first surfaces 141 at the first ends 143 of the corresponding leads 140. The second end 144 is an end in which the lead 140 extends to another side of die 110 having no bonding pad 113 for joining a integrated lead frame before cutting. The first surface 141 of lead 140 has a protruding portion 145 between the first end 143 and the second end 144, and has at least a surface uncovered by the first sealing layer 120. The soldering balls of lead-tin alloy may be attached on the protruding portion 145 (not shown in the drawing) to become the electrically outer connecting terminals of the chip scale package 100. As shown in FIG. 3, there is a smaller surface mounting width H3 between two sides of the protruding portions 145, thus a smaller surface mounting area may be gained.

The first sealing layer 120 is located on the active surface III of die 110 for protecting the die 110 from invasion of moisture and dust, made from a thermosetting and insulating material such as epoxy resin formed by molding or printing technique then curing. The first sealing layer 120 covers the active surface 111 of die 110 and the metal bonding wires 150, but at least exposes a surface of the protruding portion 145 of the leads 140. In this embodiment, the chip scale package 100 further comprises a second sealing layer 160 on the back surface 112 of die 110 for protecting the die 110 further.

Therefore, in the chip scale package 100 mentioned above, the leads 140 extending inwardly to replace the conventional metal die pad not only can carry the die 110 but also form the smaller surface mounting ends (the protruding portion 145 of the first surface 141). Due to the exposed the surface of protruding portion 145, the chip scale packages 100 mounted onto a printed circuit board would not suffer a high thermal stress from the mismatch of thermal expansion coefficients between the die 110 and the printed circuit board to avoid an improper break.

Besides, the chip scale package 100 can be manufactured by the general manufacturing equipments of lead frame package or by wafer level packaging method. At first, as shown in FIG. 5a, a wafer is provided, it comprises a plurality of uncut dies 110, each die 110 has an active surface 111 and a back surface 112. The bonding pads 113 are formed at the two lateral sides of the active surfaces 111 of the dies 110. Next, as shown in FIG. 5b, a lead frame is adhered to the wafer by a double-sided tape 130, the lead frame has a plurality of leads 140. Each lead 140 has a first surface 141, a second surface 142 adhering the active surface 111 of die 110, a first end 143, a second end 144, and a protruding portion 145 on the first surface 141 between the first end 143 and the second end 144. The first ends 143 face the corresponding bonding pads 113, the second ends 144 extend to the other lateral sides of die 110 having no bonding pads. Then, as shown in FIG. 5c, the metal bonding wires 150 are wire-bonded to electrically connect the bonding pads 113 of the die 110 with the first surfaces 141 at the first ends 143 of the corresponding leads 140. Then, as shown in FIG. 5d, the first sealing layer 120 is formed on the wafer to cover the active surface 111 of die 110 and the metal bonding wires 150, but at least to expose a surface of the protruding portions 145 of the plurality of leads 140. If there is necessity, as shown in FIG. 5e, the second sealing layer 160 is formed on the wafer which is turned over for covering the back surface 112 of die 110. If there is necessity, it is better for surface mounting to plant the soldering balls on the protruding portion 145 of lead 140. Finally, the chip scale package 100 shown in FIG. 3 is formed after cutting the wafer.

The above description of embodiments of this invention is intended to be illustrative and not limiting. Other embodiments of this invention will be obvious to those skilled in the art in view of the above disclosure.

What is claimed is:

1. A chip scale package comprising:
a die having an active surface, a plurality of bonding pads formed at the two lateral sides of the active surface of the die;
a plurality of leads on the active surface of the die, each lead having a first surface, a second surface adhering on the active surface of the die, a first end, a second end, and a protruding portion on the first surface between the first end and the second end, the first end facing the corresponding bonding pad of the die, the second end extending to a lateral side of the die having no bonding pad;
a plurality of metal bonding wires electrically connecting the bonding pads of the die with the first surfaces at the first ends of the corresponding leads; and
a first sealing layer covering the active surface of the die and the metal bonding wires, but at least exposing some surfaces of the protruding portions of the plurality of leads.

2. The chip scale package in accordance with claim 1, further comprising a second sealing layer covering a back surface of the die, wherein the back surface is corresponding to the active surface of the die.

3. The chip scale package in accordance with claim 1, wherein there is a double-sided tape for adhering the second surfaces of the leads and the active surface of the die.

4. A wafer level packaging method of a chip scale package comprising:
providing a wafer including a plurality of dies, each die having an active surface, a back surface, and a plurality of bonding pads formed at the two lateral sides of the active surface of the die;
adhering a lead frame on the wafer, the lead frame having a plurality of leads, each lead having a first surface, a second surface adhered to the active surface of the die, a first end, a second end, and a protruding portion on the first surface between the first end and the second end, the first end facing the corresponding bonding pad, the second end extending to a lateral side of the die having no bonding pad;
forming a plurality of metal bonding wires by wire-bonding to electrically connect the bonding pads of the die with the first surfaces at the first ends of the corresponding leads;
forming a first sealing layer on the wafer for covering the active surfaces of the dies and the metal bonding wires, but at least exposing some surfaces of the protruding portions of the plurality of leads; and
cutting the wafer to form a plurality of chip scale packages.

5. The wafer level packaging method of a chip scale package in accordance with claim 1, further comprising: forming a second sealing layer on the wafer for covering the back surfaces of the dies before cutting the wafer.
